(19) United States
(12) Patent Application Publication
(10) Pub. No.: US 2024/0170581 A1
(43) Pub. Date: May 23, 2024

(54) BACKSIDE CONTACTED SUB-FIN DIODES

(71) Applicant: Intel Corporation, Santa Clara, CA (US)

(72) Inventors: Cheng-Ying Huang, Hillsboro, OR (US); Ayan Kar, Portland, OR (US); Patrick Morrow, Portland, OR (US); Charles C. Kuo, Hillsboro, OR (US); Nicholas A. Thomson, Hillsboro, OR (US); Benjamin Orr, Beaverton, OR (US); Kalyan C. Kolluru, Portland, OR (US); Marko Radosavljevic, Portland, OR (US); Jack T. Kavalieros, Portland, OR (US)

(73) Assignee: Intel Corporation, Santa Clara, CA (US)

(21) Appl. No.: 17/992,057

(22) Filed: Nov. 22, 2022

(51) Int. Cl. H01L 29/861; H01L 27/02; H01L 27/06; H01L 29/06

(52) U.S. Cl. CPC H01L 29/8611; H01L 27/0255; H01L 27/0629; H01L 29/0649

(57) ABSTRACT

An integrated circuit structure includes a sub-fin having at least a first portion that is doped with a first type of dopant, and a second portion that is doped with a second type of dopant. A PN junction is between the first and second portions of the sub-fin. The first type of dopant is one of a p-type or an n-type dopant, and the second type of dopant is the other of the p-type or the n-type dopant. A first contact and a second contact comprise conductive material. In an example, the first contact and the second contact are respectively in contact with the first portion and the second portion of the sub-fin. A diode is formed based on the PN junction between the first and second portions, where the first contact is an anode contact of the diode, and the second contact is a cathode contact of the diode.

### FIELD OF THE DISCLOSURE

The present disclosure relates to integrated circuits, and more particularly, to diodes.

### BACKGROUND

Diodes are used for many different applications. For example, during an electrostatic discharge (ESD) event in an integrated circuit (IC), an input/output (I/O) terminal may experience high voltage. An ESD protection diode aims to protect the IC from failure during the ESD event. For example, a diode may be used as an ESD protection device in high-speed I/O designs, where the high voltage is grounded through the diode. In another example, a diode may be used for temperature sensing applications. Diodes used for various applications, including ESD protection applications, may need to conduct high current, such as during an ESD event. Designing diodes involves many non-trivial issues.

### BRIEF DESCRIPTION OF THE DRAWINGS

FIG. 1A illustrates a cross-sectional view of an integrated circuit structure comprising (i) a sub-fin having a first portion doped with a first type of dopant and a second portion doped with a second type of dopant, and (ii) one or more devices stacked vertically above the sub-fin, wherein a first backside contact is in contact with the first portion of the sub-fin, and a second backside contact is in contact with the second portion of the sub-fin, in accordance with an embodiment of the present disclosure.

FIG. 1B schematically illustrates a diode formed within the integrated circuit structure of FIG. 1A, in accordance with an embodiment of the present disclosure.

FIG. 1C illustrates a cross-sectional view of an integrated circuit structure that is at least in part similar to the integrated circuit structure of FIGS. 1A-1B, and that has at least some channel regions extending from a corresponding first diffusion region to a corresponding second diffusion region, in accordance with an embodiment of the present disclosure.

FIG. 2 illustrates a cross-sectional view of an integrated circuit structure that is at least in part similar to the integrated circuit structure of FIGS. 1A-1B, and that has a first backside contact at least in part extending within the first portion of the sub-fin, and a second backside contact at least in part extending within the second portion of the sub-fin, in accordance with an embodiment of the present disclosure.

FIG. 3A illustrates a cross-sectional view of an integrated circuit structure comprising (i) a sub-fin having a first portion doped with a first type of dopant and a second portion doped with a second type of dopant, and (ii) one or more laterally adjacent devices above the sub-fin, wherein a first backside contact is in contact with the first portion of the sub-fin, and a second backside contact is in contact with the second portion of the sub-fin, in accordance with an embodiment of the present disclosure.

FIG. 3B illustrates a cross-sectional view of an integrated circuit structure that is at least in part similar to the integrated circuit structure of FIG. 3A, and that has a first backside contact at least in part extending within the first portion of the sub-fin, and a second backside contact at least in part extending within the second portion of the sub-fin, in accordance with an embodiment of the present disclosure.

FIG. 4 illustrate a flowchart depicting a method of forming the integrated circuit structure of FIGS. 1A-1C, in accordance with an embodiment of the present disclosure.

FIGS. 5A, 5B, 5C, 5D, 5E, and 5F collectively illustrate cross-sectional views of an example semiconductor structure in various stages of processing in accordance with the methodology of FIG. 4, in accordance with an embodiment of the present disclosure.

FIG. 6 illustrate a flowchart depicting a method of forming the integrated circuit structure of FIG. 2, in accordance with an embodiment of the present disclosure.

FIGS. 7A, 7B, 7C, 7D, 7E, 7F, and 7G collectively illustrate cross-sectional views of an example semiconductor structure in various stages of processing in accordance with the methodology of FIG. 6, in accordance with an embodiment of the present disclosure.

FIG. 8 illustrates a computing system implemented with integrated circuit structures (such as the diode structures illustrated in FIGS. 1A-3B) formed using the techniques disclosed herein, in accordance with some embodiments of the present disclosure.

As will be appreciated, the figures are not necessarily drawn to scale or intended to limit the present disclosure to the specific configurations shown. For instance, while some figures generally indicate perfectly straight lines, right angles, and smooth surfaces, an actual implementation of an integrated circuit structure may have less than perfect straight lines, right angles (e.g., some features may have tapered sidewalls and/or rounded corners), and some features may have surface topology or otherwise be non-smooth, given real world limitations of the processing equipment and techniques used. Likewise, while the thickness of a given first layer may appear to be similar in thickness to a second layer, in actuality that first layer may be much thinner or thicker than the second layer; same goes for other layer or feature dimensions.

### DETAILED DESCRIPTION

Integrated circuit structures including diodes that use sub-fins for current conduction are provided herein. In one embodiment, one or more devices are formed above a sub-fin, where the devices may include gate-all-around (GAA) devices, fin-based devices (e.g., double-gate, tri-gate or forksheet devices), and/or other appropriate devices (e.g., planar devices). In an example, the devices may be vertically stacked devices (three-dimensional or 3D architecture), and/or laterally adjacent devices (two-dimensional or 2D architecture). In an example, a diode is formed based on a PN junction between appropriately doped first and second portions of the sub-fin. In an example, the first portion is p-doped and the second portion is n-doped, and a first backside conductive contact (e.g., one of anode or cathode contact of the diode) is in contact with the first portion, and a second backside conductive contact (e.g., the other of the anode or cathode contact of the diode) is in contact with the second portion. The diode structure can be used in any number of applications, and may be well-suited for electrostatic discharge (ESD) protection applications.

In another embodiment, an integrated circuit structure includes a sub-fin having at least a first portion that is doped with a first type of dopant, and a second portion that is doped with a second type of dopant. A PN junction is between the first and second portions of the sub-fin. The first type of dopant is one of a p-type or an n-type dopant, and the second type of dopant is the other of the p-type or the n-type dopant. A first contact and a second contact comprise conductive material. In an example, the first contact and the second contact are respectively in contact with the first portion and the second portion of the sub-fin. A diode is formed based on the PN junction between the first and second portions, where the first contact is an anode contact of the diode, and the second contact is a cathode contact of the diode.

In yet embodiment, a diode structure comprises a sub-fin having (i) a first portion that is an anode region, and (ii) a second portion that is a cathode region, with a PN junction between the first and second portions. A first backside contact is in contact with the first portion of the sub-fin, and a second backside contact is in contact with the second portion of the sub-fin.

In a further embodiment, an integrated circuit structure comprises a sub-fin having a first portion and a second portion, with a PN junction at an interface between the first and second portions. A first diffusion region extends upward from the first portion of the sub-fin, and a second diffusion region extends upward from the second portion of the sub-fin. A first body of semiconductor material extends laterally from the first diffusion region, and a second body of semiconductor material extends laterally from the second diffusion region. A first conductive contact is in contact with the first portion of the sub-fin, and a second conductive contact is in contact with the second portion of the sub-fin. Numerous configurations and variations will be apparent in light of this disclosure.

In any such embodiments, another portion of the sub-fin may be removed and replaced with some fill material (e.g., dielectric fill, such as silicon dioxide), such that an imaginary horizontal line passes through the PN junction and the fill material that is laterally adjacent to the unremoved sub-fin portion in which the PN junction resides. In an example, a logic transistor may be above the fill material (e.g., there may not be a sub-fin below the logic transistor).

### General Overview

As mentioned herein above, there are various non-trivial issues associated with designing diodes. For example, utilizing the underlying bulk substrate as a current path for a diode increases the performance of the diode. As an example, in a gate-all-around (GAA) or a fin-based diode device, using the underlying bulk substrate for current conduction during an ESD event increases the current carrying capability of the diode, due to relatively large cross sectional area of the bulk substrate. However, configurations where bulk substrate is removed cannot accommodate such diodes. For example, formation of backside interconnect features for signal and/or power routing may necessitate removal of the bulk substrate, in which case the diodes cannot rely on the bulk substrate for current conduction. Furthermore, a substrate-based diode having diode contacts on the frontside can be difficult to implement, such as in the case where devices are vertically stacked on top of each other in a 3D architecture. For example, if an NMOS device is on top of (e.g., above) a PMOS device, or vice versa, an n-type diffusion region may be on top of a p-type diffusion region (or the opposite), resulting in possibly forming a diode junction between the two diffusion regions, rather than formation of a diode junction within the substrate.

Accordingly, techniques are provided herein to form a sub-fin diode that uses a sub-fin as a current conduction path, in which a first contact (e.g., one of anode or cathode contact) and a second contact (e.g., the other anode or cathode contact) of the diode are both on a backside (e.g., below) of the sub-fin. For example, the sub-fin comprises at least a first portion doped with a first type of dopant, and a second portion doped with a second type of dopant. The first type of dopant is one of a p-type or an n-type dopant, and the second type of dopant is the other of the p-type or the n-type dopant. A PN junction is formed at a junction or interface between the first and second portions of the sub-fin, thereby forming a diode within the sub-fin. Backside conductive contacts are used for the diode. For example, a first contact is coupled to (e.g., in contact with) the first portion of the sub-fin, and a second contact is coupled to (e.g., in contact with) the second portion of the sub-fin. Thus, the current conduction path is through the first contact, the first portion of the sub-fin, the second portion of the sub-fin, and the second contact.

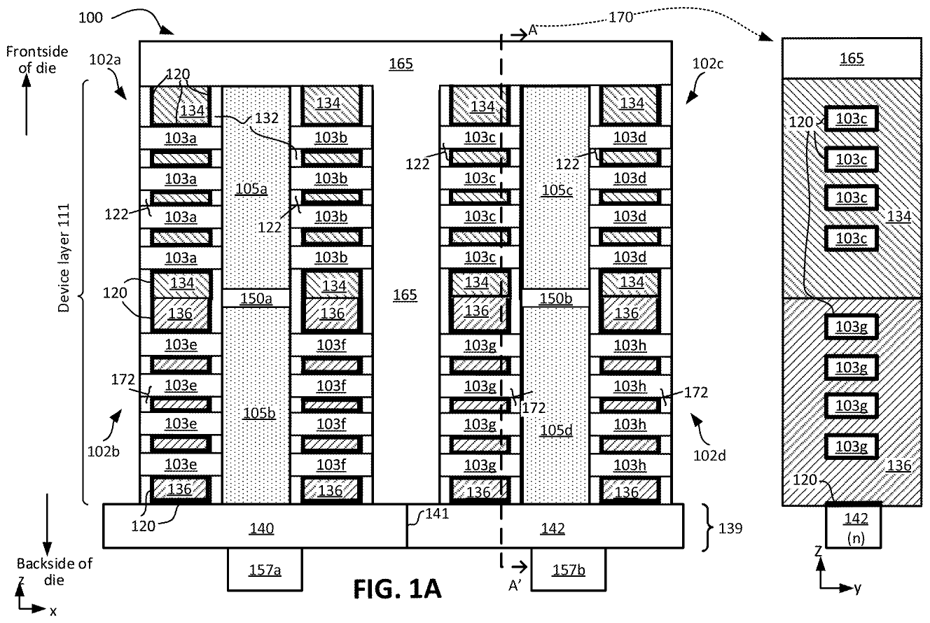

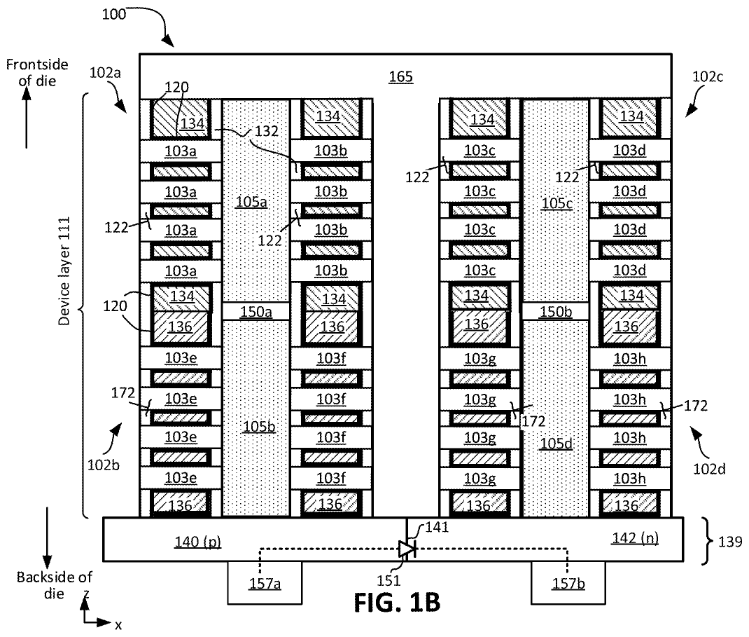

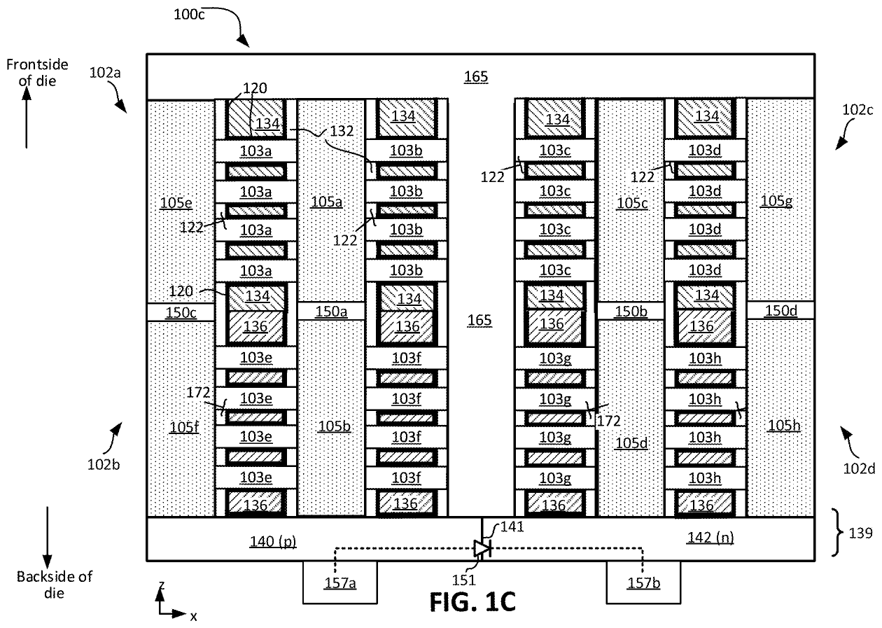

In one such example embodiment, one or more devices may be formed above the sub-fin. For example, FIGS. 1A-1C discussed herein below illustrate vertically stacked gate-all-around (GAA) devices above the sub-fin. In such example devices, GAA channel regions include one or more nanoribbons or other form of channel regions (such as nanowires) around which a gate structure wraps. In other examples, the devices may be fin-based devices, where the fin-based channel region is wrapped in part by a gate structure (e.g., a tri-gate like structure, such as in the case of a finFET or forksheet device). To this end, the use of a specific channel region configuration (e.g., nanoribbon or fin) is not intended to limit the present description to that specific channel configuration. Rather, the techniques provided herein can benefit any number of non-planar channel configurations, whether those bodies be nanowires, nanoribbons, nanosheets, fins, or some other body around which a gate structure can at least partially wrap, as well as planar channel configurations.

Continuing again with the example of vertically stacked devices above the sub-fin, for example, a first upper device and a first lower device is above the first portion of the sub-fin, and a second upper device and a second lower device is above the second portion of the sub-fin. In an example, each of the devices have one or more corresponding diffusion regions. The diffusion regions may be epitaxially formed regions, and may be similar to (e.g., similar shape and/or doping levels) source or drain regions of logic transistors formed on the same die or substrate, in some examples. For example, a diffusion region of the first lower device may be above the first contact, and a diffusion region of the second lower device may be above the second contact. In an example, there may not be any diffusion region above the PN junction between the first and second portions of the sub-fin. Rather, a structure comprising dielectric material may be above the PN junction between the first and second portions of the sub-fin. In some such cases, the dielectric structure can be in place of what would otherwise be another diffusion region.

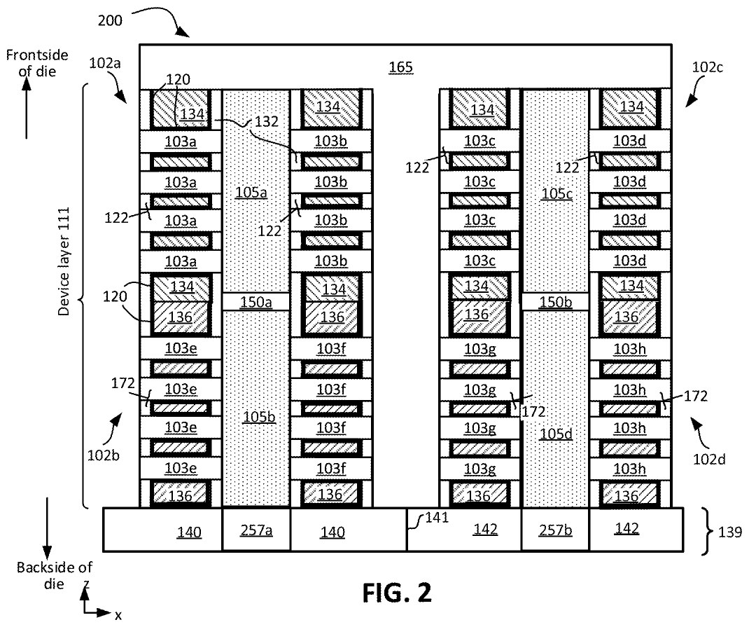

The above discussed first and second contacts are backside contacts, which access the first and second portions, respectively, of the sub-fin from the backside. In an example, the first and second contacts are in contact with a backside surface of the sub-fin (e.g., see FIGS. 1A-1C). In another example, the first and second contacts may at least in part extend within the first and second portions, respectively, of the sub-fin (e.g., see FIG. 2), and may be in contact with the diffusion regions of the above discussed first and second lower devices, respectively.

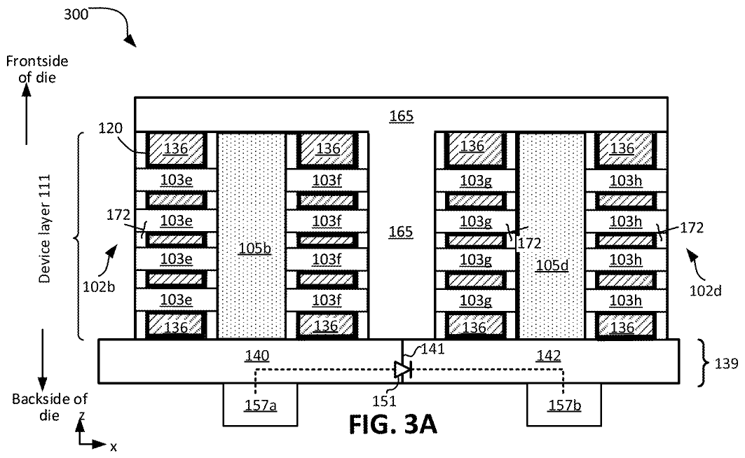

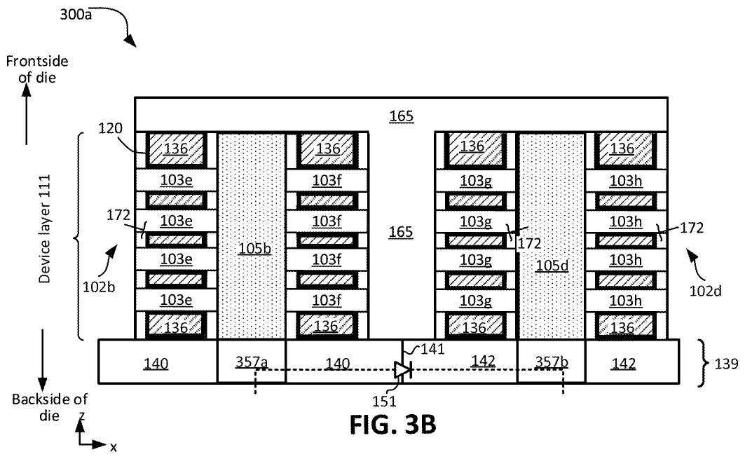

In one embodiment, the devices above the sub-fin may also be arranged to be laterally adjacent to each other in a 2D fashion, e.g., instead of being vertically stacked in a 3D fashion, such as illustrated in FIGS. 3A and 3B. Similar to the 3D architecture, the first and second contacts may be in contact with a backside surface of the sub-fin (e.g., see FIG. 3A), or may at least in part extend within the first and second portions, respectively, of the sub-fin (e.g., see FIG. 3B). In an example, the first and second contacts are formed from the backside of the structure. For example, after formation of the devices above the sub-fin, the structure is flipped, such that the backside of the devices in now on the top. In this flipped orientation, sections of the sub-fin are implanted with corresponding dopants, e.g., to form the above discussed first and second portions of the sub-fin. A low temperature anneal process may be used to activate the dopants, in an example. The first and second contacts are then formed from the backside.

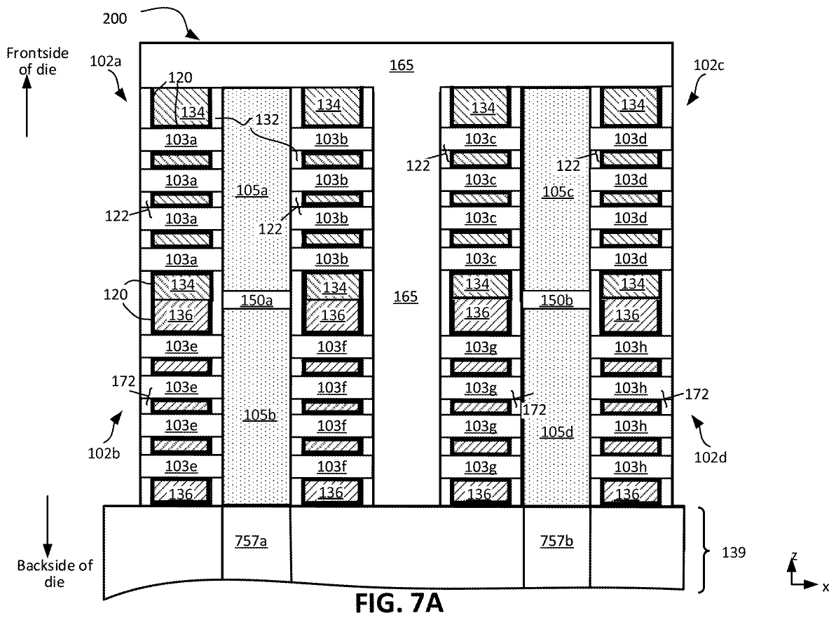

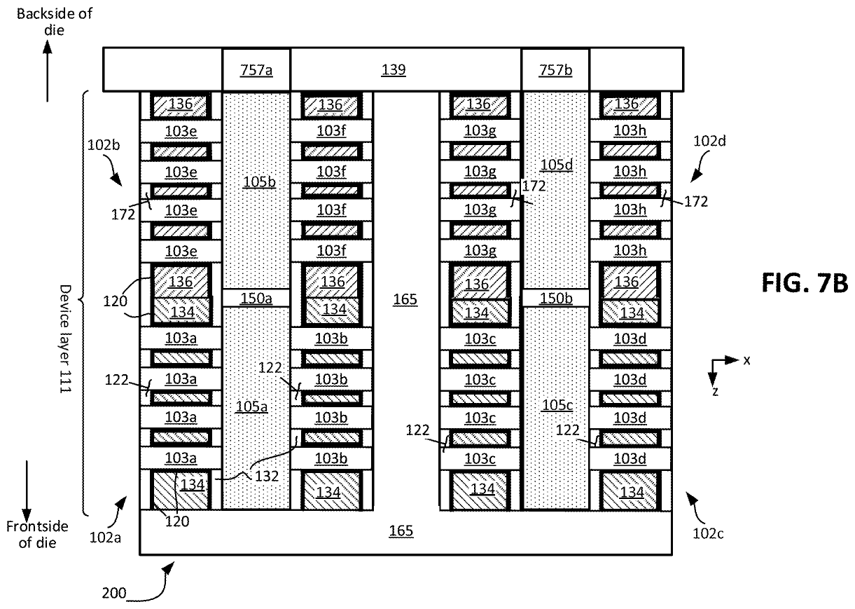

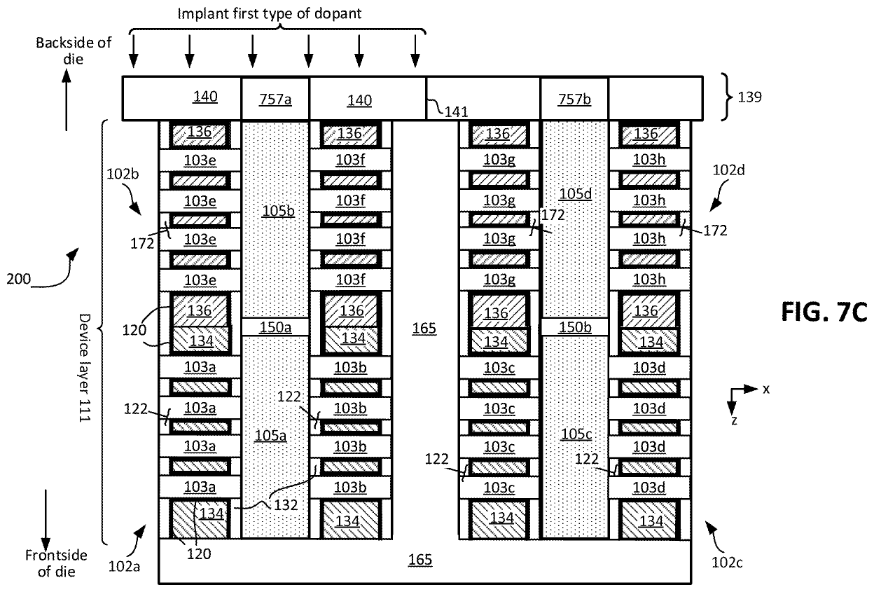

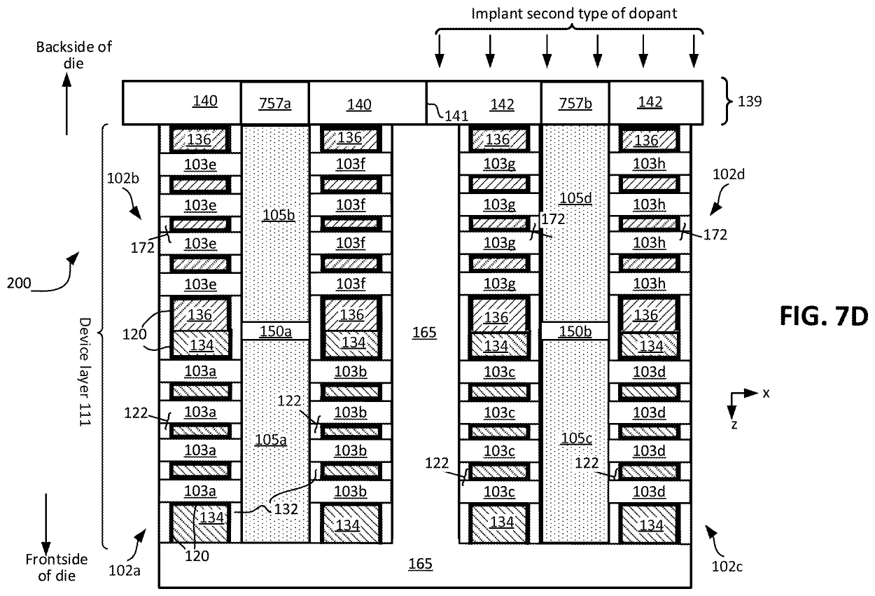

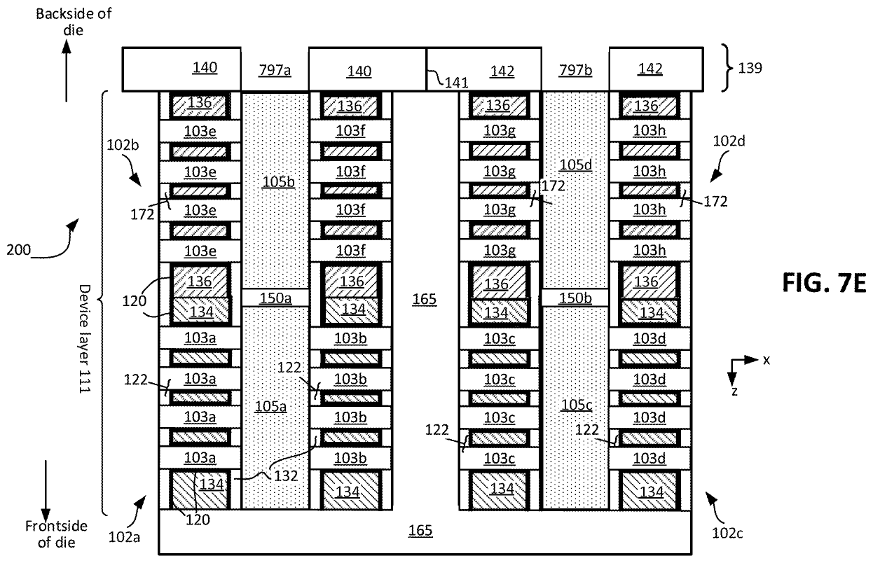

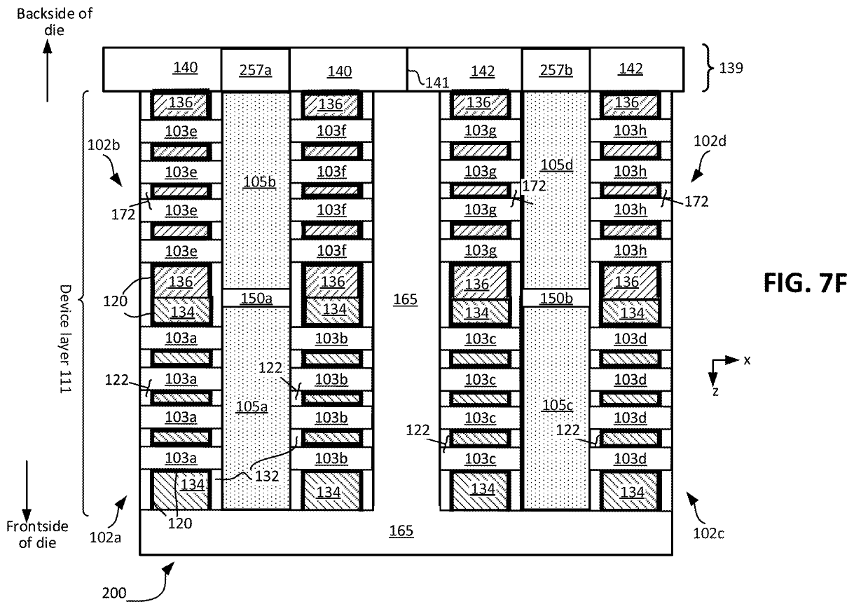

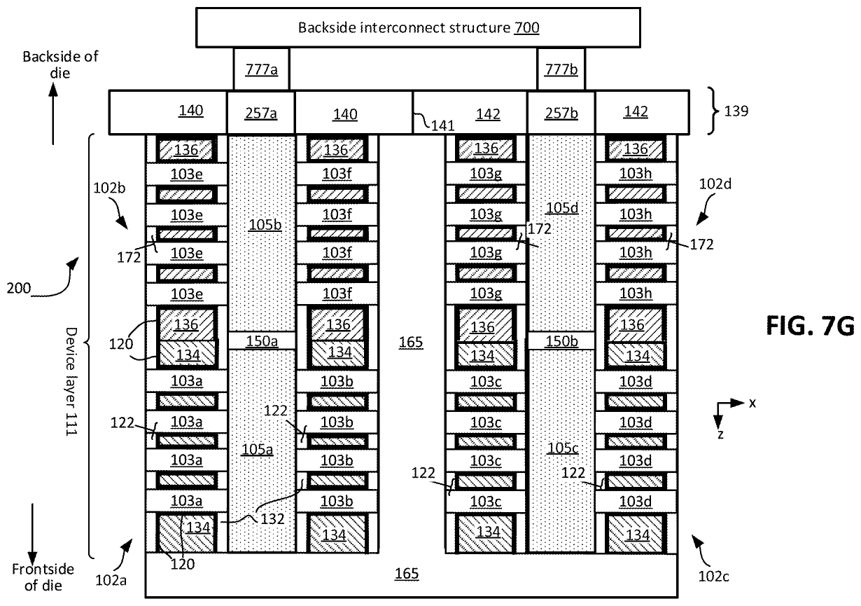

In the example where the contacts at least in part extend within the sub-fin, sacrificial materials initially extend within the sub-fin (e.g., see sacrificial materials 757a, 757b of FIGS. 7A-7D). In an example, the sacrificial materials are formed to extend within the sub-fin from the frontside. Subsequently, from the backside, the sacrificial materials 757a, 757b are replaced with conductive material (such as one or more metals, and/or alloys thereof), to form the first and second contacts, e.g., see FIGS. 7E and 7F. In some such examples, the place holder sacrificial material deposited where the first and second contacts will eventually be formed is provisioned earlier in the process, such as during the source and drain (diffusion region) processing from the frontside. For instance, in some such cases, the recesses where the diffusion regions are formed are etched slightly deeper so as to extend into the sub-fin region, and that excess recess area is filled with the place holder sacrificial material (e.g., silicon nitride). Then the diffusion regions can be epitaxially grown above that place holder material. During subsequent backside processing, the place holder material can be exposed by way of a backside polish, and removed (e.g., selective etch) and replaced with the conductive material of the first and second contacts (e.g., tungsten, titanium or titanium nitride). In this manner, the first and second contacts are self-aligned to their respective diffusion regions (because they are formed in same trench or recess).

The use of “group IV semiconductor material” (or “group IV material” or generally, “IV”) herein includes at least one group IV element (e.g., silicon, germanium, carbon, tin), such as silicon (Si), germanium (Ge), silicon-germanium (SiGe), and so forth. The use of “group III-V semiconductor material” (or “group III-V material” or generally, “III-V”) herein includes at least one group III element (e.g., aluminum, gallium, indium) and at least one group V element (e.g., nitrogen, phosphorus, arsenic, antimony, bismuth), such as gallium arsenide (GaAs), indium gallium arsenide (InGaAs), indium aluminum arsenide (InAlAs), gallium phosphide (GaP), gallium antimonide (GaSb), indium phosphide (InP), gallium nitride (GaN), and so forth. Note that group III may also be known as the boron group or IUPAC group 13, group IV may also be known as the carbon group or IUPAC group 14, and group V may also be known as the nitrogen family or IUPAC group 15, for example.

Materials that are “compositionally different” or “compositionally distinct” as used herein refers to two materials that have different chemical compositions. This compositional difference may be, for instance, by virtue of an element that is in one material but not the other (e.g., SiGe is compositionally different than silicon), or by way of one material having all the same elements as a second material but at least one of those elements is intentionally provided at a different concentration in one material relative to the other material (e.g., SiGe having 70 atomic percent germanium is compositionally different than from SiGe having 25 atomic percent germanium). In addition to such chemical composition diversity, the materials may also have distinct dopants (e.g., gallium and magnesium) or the same dopants but at differing concentrations. In still other embodiments, compositionally distinct materials may further refer to two materials that have different crystallographic orientations. For instance, (110) silicon is compositionally distinct or different from (100) silicon. Creating a stack of different orientations could be accomplished, for instance, with blanket wafer layer transfer. If two materials are elementally different, then one of the material has an element that is not in the other material.

Use of the techniques and structures provided herein may be detectable using tools such as electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDX); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. For example, in some embodiments, such tools may be used to detect a sub-fin having at least (i) a first portion doped with a first type of dopant and (ii) a second portion doped with a second type of dopant, and a first backside conductive contact and a second backside conductive contact respectively in contact with the first portion and the second portion of the sub-fin. In some embodiments, such tools may be used to detect vertically stacked devices above the sub-fin, or laterally adjacent devices above the sub-fin. In some further embodiments, such tools may be used to detect that other portions of the sub-fin have been removed (such as under logic device area). Numerous configurations and variations will be apparent in light of this disclosure.

Elements referred to herein with a common reference label followed by a particular number or alphabet may be collectively referred to by the reference label alone. For example, diffusion regions 105a, 105b, 105c, 105d of FIG. 1A may be collectively and generally referred to as diffusion regions 105 in plural, and diffusion region 105 in singular.

### Architecture

FIG. 1A illustrates a cross-sectional view of an integrated circuit structure 100 comprising (i) a sub-fin 139 having a first portion 140 doped with a first type of dopant and a second portion 142 doped with a second type of dopant, and (ii) one or more devices 102a, 102b, 102c, 102d stacked vertically above the sub-fin 139, wherein a first backside contact 157a is in contact with the first portion 140 of the sub-fin 139, and a second backside contact 157b is in contact with the second portion 142 of the sub-fin 139, in accordance with an embodiment of the present disclosure.

As can be seen, the cross-sectional view of FIG. 1A is taken parallel to, and through, the channel regions 103, such that the channel regions 103 of the structure 100, and epitaxially formed diffusion regions 105 are shown.

In the structure 100, a device 102a is stacked above a device 102b, and a device 102c is stacked above a device 102d. In an example, individual ones of the devices 102 are gate-all-around (GAA) devices, in which a gate structure 122 or 172 wraps around individual channel regions 103. In an example, individual channel regions 103 are nanoribbons. As will be further appreciated in light of this disclosure, reference to nanoribbons is also intended to include other channel regions, such as nanowires or nanosheets, and other such semiconductor bodies around which a gate structure at least in part wraps around, such as fins. To this end, the use of a specific channel region configuration (e.g., GAA or nanoribbons) is not intended to limit the present description to that specific channel configuration. In an example, the teachings of this disclosure may also be applicable to devices in which the gate at least partially wrap around the channel region, such as fin-based devices (e.g., double-gate, tri-gate, or forksheet devices). Thus, a stack of nanoribbon channel regions 103 may be replaced by a corresponding fin, in one example. Similarly, a stack of nanoribbon channel regions 103 may be replaced by a corresponding stack of nanowires or nanosheets, in another example.

In the structure 100, in an example, individual devices 102 comprises corresponding diffusion region 105 (e.g., each device 102 has one corresponding diffusion region). However, a device 102 may have more than one diffusion region, as discussed herein below with respect to FIG. 1C.

Referring again to FIG. 1A, the diffusion regions 105 may be epitaxially formed regions, and may be similar to (e.g., similar shape and/or doping levels) source or drain regions of logic transistors. For example, the diffusion regions 105 may act as source or drain regions of the various devices 102. However, in an example, for reasons discussed herein below, the channel regions and/or the diffusion regions of the devices 102a, 102b, 102c, 102d may no conduct any meaningful or substantial amount of current.

In general, in a GAA transistor, the channel region extends between a first source or drain region (e.g., a first diffusion region) and a second source or drain region (e.g., a second diffusion region). However, in the structure 100 of FIG. 1A, the nanoribbons 103 extend from a diffusion region, but is not necessarily between two diffusion regions. For example, in the device 102a, nanoribbons 103a and 103b extend in two opposite directions from the diffusion region 105a. Similarly, in the device 102b, nanoribbons 103e and 103f extend in two opposite directions from the diffusion region 105b. Similarly, in the device 102c, nanoribbons 103c and 103d extend in two opposite directions from the diffusion region 105c. Also, in the device 102d, nanoribbons 103g and 103h extend in two opposite directions from the diffusion region 105d.

In an example (and as will be discussed herein below with respect to FIG. 1C), further diffusion regions may be on a left side of the nanoribbons 103a, 103e, such that each of the stacks of the nanoribbons 103a and 103e extend between two corresponding diffusion regions. Similarly, in an example, further diffusion regions may be on a right side of the nanoribbons 103d, 103h, such that each of the stacks of the nanoribbons 103d and 103h extend between two corresponding diffusion regions.

In the example of FIG. 1A, the device 102a comprises a stack of nanoribbons 103a and a stack of nanoribbons 103b; the device 102b comprises a stack of nanoribbons 103e and a stack of nanoribbons 103f; the device 102c comprises a stack of nanoribbons 103c and a stack of nanoribbons 103d; and the device 102d comprises a stack of nanoribbons 103g and a stack of nanoribbons 103h. In the example of FIG. 1A, each stack of nanoribbons 103 (such as stack of nanoribbons 103a, 103b, . . . , 103h) include four nanoribbons. Other examples may include fewer nanoribbons per channel region (e.g., one or two or three), or more nanoribbons per channel region (e.g., five or six). Still other embodiments may include other channel configurations, such as one or more nanowires or a fin or other semiconductor body, including both planar and nonplanar topologies, as discussed herein above.

In an example, the upper devices 102a, 102c comprise gate structures 122 and the lower devices 102b, 102d comprise gate structures 172. Gate spacers 132 isolates the gate structures 122, 172 from contacting the various diffusion regions 105. In other embodiments, there may be other insulator layers (e.g., interlayer dielectric) that prevent such contact, whether in addition to the gate spaces 132, or in place of the gate spacers 132. In one embodiment, each of gate structures 122, 172 wraps around corresponding nanoribbons 103 in the corresponding channel region.

Note that in the example structure 100 of FIG. 1A, the gate structures 122, 172 may not be contacted. Thus, there may not be a gate contact that is in contact with the corresponding gate electrode of a gate structure.

Each of gate structures 122, 172 can be formed via gate-first or gate-last processing, and may include any number of suitable gate materials and configurations. In an embodiment, each of the gate structures 122, 172 includes a corresponding gate electrode and a gate dielectric 120 between the gate electrode and the corresponding nanoribbons 103. In one example the gate spacers 132 may be considered part of the gate structure, whereas in another example the gate spacers 132 may be considered external to the gate structure.

Each of the gate structures 122 of the upper devices 102a, 102c comprises corresponding gate electrodes 134 and corresponding dielectric material 120. Each of the gate structures 172 of the lower devices 102b, 102d comprises a corresponding gate electrode 136 and corresponding dielectric material 120. The gate dielectric material 120 (shown with thick bolded lines) warps around middle section of individual nanoribbons 103 (note that end sections of individual nanoribbons 103 are wrapped around by the gate spacers 132). The gate dielectric material 120 is between individual nanoribbons 103 and corresponding gate electrode, as illustrated. In an example, due to conformal deposition of the gate dielectric material 120, the gate dielectric material 120 may also be on inner sidewalls of the gate spacers 132, and may also be on a top surface of at least sections of the sub-fin 139 (e.g., between the gate electrodes and the sub-fin 139), as illustrated.

The gate dielectric 120 may include a single material layer or multiple stacked material layers. The gate dielectric may include, for example, any suitable oxide (such as silicon dioxide), high-k dielectric material, and/or any other suitable material as will be apparent in light of this disclosure. Examples of high-k dielectric materials include, for instance, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, to provide some examples. The high-k dielectric material (e.g., hafnium oxide) may be doped with an element to affect the threshold voltage of the given semiconductor device. According to some embodiments, the doping element used in gate dielectric 120 is lanthanum. In some embodiments, the gate dielectric can be annealed to improve its quality when high-k dielectric material is used. In some embodiments, the gate dielectric 120 includes a first layer (e.g., native oxide of nanoribbons, such as silicon dioxide or germanium oxide or SiGe-oxide) on the nanoribbons, and a second layer of high-k dielectric (e.g., hafnium oxide) on the first layer. In an example, different devices may have elementally and/or compositionally different gate dielectric 120. For example, a high-k gate dielectric used for a PMOS device may be elementally and/or compositionally different from a high-k gate dielectric used for an NMOS device. In an example, the upper device 102a may have a different high-k gate dielectric than the high-k gate dielectric used for the lower device 102b. In an example, using dipole material for transistor Vt tuning may result in different high-k materials for the upper devices 102a, 102c and the lower devices 102b, 102d.

In an example, the gate electrodes 134 and the gate electrodes 136 may include any sufficiently conductive material, such as a metal, metal alloy, or doped polysilicon. The gate electrodes may include a wide range of materials, such as polysilicon or various suitable metals or metal alloys, such as aluminum, tungsten, titanium, tantalum, copper, cobalt, molybdenum, titanium nitride, or tantalum nitride, for example.

In the example of FIG. 1A, a gate electrode 134 and a gate electrode 136 are arranged in a vertically stacked configuration, without any isolation structure between the two vertically stacked gate electrodes. However, in another example, two vertically stacked gate electrodes 134, 136 may be separated by a corresponding isolation structure comprising dielectric material.

In one embodiment, one or more work function materials may be included around the nanoribbons 103. Note that work function materials are called out separately, but may be considered to be part of the gate electrodes. In this manner, a gate electrode may include multiple layers or components, including one or more work function materials, gate fill material, capping or resistance-reducing material, to name a few examples. In some embodiments, a p-channel device may include a work function metal having titanium, and an n-channel device may include a work function metal having tungsten or aluminum, although other material and combination may also be possible. In some other embodiments, the work function metal may be absent around one or more nanoribbons 103. In still other embodiments, there may be insufficient room for any gate fill material, after deposition of work function material (a given gate electrode may be all work function material and no fill material). Numerous gate structure configurations can be used along with the techniques provided herein, and the present disclosure is not intended to be limited to any particular such configurations.

The semiconductor bodies 103a, 103b, . . . , 103h, which in this case are nanoribbons, can be any number of semiconductor materials as well, such as group IV material (e.g., silicon, germanium, or SiGe) or group III-V materials (e.g., indium gallium arsenide). In other embodiments, the semiconductor bodies 103 may be fins on which the corresponding gate structures are formed to provide double-gate or tri-gate configurations (as opposed to gate-all-around configurations with nanoribbons or wires). The semiconductor bodies 103 may be lightly doped, or undoped, and may be shaped or sculpted during the gate formation process, according to some embodiments. In some cases, semiconductor bodies 103 may be a multilayer structure, such as a SiGe body cladded with germanium, or a silicon body cladded with SiGe. Any number of channel configurations can be used.

Referring to the left most-set of nanoribbons 103a of the upper device 102a and the left most-set of nanoribbons 103e of the lower device 102b, the nanoribbons 103a and 103e can be formed form the same fin structure. Similarly, other vertically adjacent sets of nanoribbons (such as nanoribbons 103b, 103f) can be formed from the same fin structure. Note that the top and bottom channel regions of the fin structure may be compositionally and/or structurally configured the same or differently, with respect to shape and/or semiconductor materials, and may further include fin-based channel regions, nanowire-based channel regions, or nanoribbon-based channel regions. For instance, the lower portion of the fin structure comprises, for example, SiGe or germanium suitable for PMOS devices interleaved with sacrificial material, and the upper portion of the fin structure comprise a group III-V semiconductor material such as indium gallium arsenide, indium arsenide, or gallium antimonide suitable for NMOS devices interleaved with sacrificial material. In another example embodiment, the lower channel region is configured with a first fin portion of the fin structure comprising a first semiconductor material (e.g., SiGe), and the upper channel region is configured with a second fin portion of the fin structure comprising a second semiconductor material (e.g., silicon) that is compositionally different from the first semiconductor material.

As can further be seen in FIG. 1A, non-conductive isolation structure 150 isolates diffusion region of an upper device from a diffusion region of a lower device. For example, isolation structure 150a comprising dielectric material is between the diffusion region 105a of the upper device 102a and the diffusion region 105b of the lower device 102b, and electrically isolates the two diffusion regions. Similarly, isolation structure 150b comprising dielectric material is between the diffusion region 105c of the upper device 102c and the diffusion region 105d of the lower device 102d, and electrically isolates the two diffusion regions. In an example, the isolation structures 150 comprise dielectric material, e.g., one or more appropriate oxides, nitrides, carbides, oxynitrides, oxycarbides, and oxycarbonitrides. In some example embodiments, isolation structures 150 include silicon, and one or more of oxygen, carbon, and nitrogen (e.g., silicon oxycarbide, or silicon oxycarbonitride). In an example, one or both the isolation structures 150a, 150b may be absent from the structure 100, such that an upper diffusion region is in contact with a lower diffusion region. In an example, instead of an isolation structure 150a and/or 150b, a corresponding conductive structure, such as a conductive via structure (e.g., comprising one or more metals and/or alloys thereof) may be present between a corresponding upper diffusion region and a corresponding lower diffusion region. In an example, such a conductive via structure can electrically couple an upper diffusion region (e.g., diffusion region 150b) and a lower diffusion region (e.g., diffusion region 150a). Whether an isolation structure 150 or a corresponding conductive structure is present between an upper and a lower diffusion region may be based on a design of the corresponding circuit.

The diffusion regions 105a, . . . , 105d (e.g., each of which may be a source or drain region) can be any suitable semiconductor material and may include any dopant scheme. In an example, a diffusion region 105 can be a PMOS source or drain region that include, for example, group IV semiconductor materials such as silicon, germanium, SiGe, germanium tin (GeSn), SiGe alloyed with carbon (SiGe:C). Example p-type dopants include boron, gallium, indium, and aluminum. Another diffusion region 105 can be an NMOS source or drain region that include, for example, silicon or group III-V semiconductor materials such as two or more of indium, aluminum, arsenic, phosphorus, gallium, and antimony, with some example compounds including but not limited to indium aluminum arsenide, indium arsenide phosphide, indium gallium arsenide, indium gallium arsenide phosphide, gallium antimonide, gallium aluminum antimonide, indium gallium antimonide, or indium gallium phosphide antimonide. In one specific embodiment, PMOS diffusion regions are boron-doped SiGe, and NMOS diffusion regions are phosphorus-doped silicon. In a more general sense, the diffusion regions, e.g., the source and drain regions, can be any semiconductor material suitable for a given application. In some cases, the epitaxial diffusion regions may include a multilayer structure, such as a germanium cap on a SiGe body, or a germanium body and a carbon-containing SiGe spacer or liner between the corresponding channel region and that germanium body. In any such cases, a portion of the epi source and drain regions may have a component that is graded in concentration, such as a graded germanium concentration to facilitate lattice matching, or a graded dopant concentration to facilitate low contact resistance. Any number of source and drain configurations can be used as will be appreciated, and the present disclosure is not intended to be limited to any particular such configurations.

In an example, one or more of the devices 102a, . . . , 102d are PMOS devices, and another one or more of the devices 102a, . . . , 102d are NMOS devices. In an example, the lower devices 102b, 102d are PMOS devices and the upper devices 102a, 102c are NMOS devices (although in another example, the lower devices can be NMOS devices and the upper devices can be PMOS devices).

In an example, the diffusion regions 105 lack corresponding diffusion contacts (such as source or drain contacts). Thus, in FIG. 1A, the diffusion regions 105 of the structure may not be contacted (note that in FIG. 2 discussed herein below, the lower diffusion regions have corresponding backside contacts).

In an example, the devices 102a, . . . , 102d are at least in part above a sub-fin 139. In an example, the sub-fin 139 comprises appropriately doped semiconductor material, such as the same semiconductor material (or different semiconductor material) as the channel regions 103. FIG. 1A also illustrates a cross-sectional view 170 of the structure 100, along line A-A′, and this view shows the cross-sectional view of the vertically channel regions 103c, 103g, and the gate electrodes 134, 136 respectively wrapping around the channel regions 103c, 103g. Note that as illustrated in the cross-sectional view 170 of FIG. 1A, the sub-fin 139 may be below the channel regions 103, and not below sections that do not include the nanoribbon channel regions 103.

The sub-fin 139 comprises a portion 140 laterally adjacent to another portion 142, with an interface or junction 141 therebetween. In one embodiment, the portions 140, 142 are doped differently, e.g., have different dopant types. For example, the portion 140 is doped with a first type of dopant, and the portion 142 is doped with a second type of dopant, wherein the first type of dopant is one of a p-type or an n-type dopant, and wherein the second type of dopant is the other of the p-type or the n-type dopant. This results in a PN junction 141 between the portion 140 and portion 142, resulting in a formation of a diode, as will be described herein in further detail in turn. Example p-type dopants include boron, gallium, indium, and aluminum. Example n-type dopants include phosphorous and arsenic. In an example, the portions 140 and 142 may have appropriate doping concentrations, e.g., a concentration in the range of 1E16 to 1E24 atoms per cubic cm, and the doping concentration may be implementation specific.

Note that the devices 102a, . . . , 102d are formed within a device layer 111 of the structure 100. Above the device layer 111 is the frontside of the die, and below the device layer is the backside of the die, as schematically illustrated in FIG. 1A using corresponding arrows. In one embodiment, the structure 100 is accessed from the backside of the die, e.g., using the backside sub-fin contacts 157a and 157b (also referred to herein as “backside contacts 157a and 157b”, or simply as “contacts 157a and 157b”). The backside contacts 157a and 157b comprise conductive material, such as one or more metals and/or alloys thereof. The backside contact 157a is coupled to (e.g., in contact with) the portion 140, and the backside sub-fin contact 157b is coupled (e.g., in contact with) to the portion 142 of the sub-fin 139, as illustrated.

As illustrated, the diffusion region 105b is above and on the portion 140 of the sub-fin 139, and the diffusion region 105d is above and on the portion 142 of the sub-fin 139. As also illustrated, in an example, no diffusion region is above a junction 141 between the portions 140, 142 of the sub-fin 139. For example, a dielectric material 165 is above the junction 141 and between the nanoribbons 103b, 103f and the nanoribbons 103c, 103g. In an example, the dielectric material 165 may also be above the diffusion regions 105a, 105c and/or above the gate structures 122. Thus, for example, the nanoribbons 103b laterally extend from the diffusion region 105a to the dielectric material 165, the nanoribbons 103f laterally extend from the diffusion region 105b to the dielectric material 165, and so on.

FIG. 1B schematically illustrates a diode 151 formed within the structure 100 of FIG. 1A, in accordance with an embodiment of the present disclosure. For example, as discussed with respect to FIG. 1A above, the portion 140 of the sub-fin 139 is doped with a first type of dopant, and the portion 142 of the sub-fin 139 is doped with a second type of dopant, wherein the first type of dopant is one of a p-type or an n-type dopant, and wherein the second type of dopant is the other of the p-type or the n-type dopant. This results in formation of the PN junction 141 between the portion 140 and portion 142, resulting in a formation of the diode 151, as illustrate in FIG. 1B.

In an example, depending on whether the above discussed first or second type of dopants are p or n-type of dopants, the portions 140 and 142 form one of a cathode region or an anode region of the diode 151. For example, the portion 140 may be doped with a p-type dopant, and the portion 142 may be doped with an n-type dopant. Accordingly, the portion 140 may be an anode region and the backside contact 157a may be an anode contact of the diode 151, and the portion 142 may be a cathode region and the backside contact 157b may be a cathode contact of the diode 151, where the polarity of the diode 151 is as illustrated in FIG. 1B. As will be appreciated, the various portions 140, 142 of the sub-fin 139 can be doped in an opposite manner, which will still result in formation of the diode 151, but with a reversed polarity, and the cathode and anode regions and contacts will also be reversed.

Note that the current conduction path of the diode 151 is through the contacts 157a, 157b, and the portions 140, 142 of the sub-fin 139. Thus, the main conduction path of the diode 151 is through the sub-fin 139, and the diode 151 is a sub-fin diode 151 having backside contacts 157a, 157b. Thus, the diode 151 is a backside contacted sub-fin diode.

As discussed, the current may not conduct through the diffusion regions 105a, . . . , 105d and/or through the nanoribbons 103a, . . . , 103h. The nanoribbons 103 and the diffusion regions 105, thus, do not provide any functionality to the diode 151.

Although the nanoribbons 103 and/or the diffusion regions 105 may not provide much useful functionality to the diode 151 of the structure 100, the nanoribbons 103 and the diffusion region 105 are formed as a standard process of forming nanoribbons and diffusion regions within a section of a die comprising the structure 100. For example, the devices 102a, . . . , 102d and the diode structure 151 may be adjacent to other devices, such as GAA transistors (e.g., logic transistors), and same standard processes may be applied to form the devices 102a, . . . , 102d and the logic transistors. Thus, even though the nanoribbons 103 and/or the diffusion regions 105 may not provide much useful functionality to the diode 151 of the structure 100, the nanoribbons 103 and the diffusion region 105 may nonetheless be present in the structure 100. As discussed herein, the nanoribbons 103 and the gate structures 122, 172 may not play any functional role in the function of the diode 151. Accordingly, in an example, the gate structures 122 and/or 172 may be absent from the structure 100. For example, a polysilicon dummy gate or a dielectric material structure may be present instead of the gate structures 122 and/or 172.

In an example, for stacked transistor architecture (where a GAA or FinFET device is stacked above another GAA or FinFET device, such as devices 102a and 102b), the sub-fins may be thinned or even removed, e.g., to facilitate formation of backside diffusion region contacts and/or gate electrode contacts for the lower devices of the stacked transistor architecture. Accordingly, stacked logic transistors may lack a sub-fin, in one example. In contrast, in the structure 100, at least a section of the sub-fin 139 is preserved, to form the above discussed diode 151. Thus, the structure 100 and a logic transistor may be laterally adjacent, where the structure 100 comprises the sub-fin 139, and where the logic transistor lacks a sub-fin below the logic transistor. For example, a section of the sub-fin below the logic transistor may be replaced by fill material (e.g., dielectric fill, such as silicon dioxide). Thus, an imaginary horizontal line passes through the PN junction 141 and the portions 140, 142, and also passes through the fill material that is below the logic transistor.

FIG. 1C illustrates a cross-sectional view of an integrated circuit structure 100c that is at least in part similar to the integrated circuit structure 100 of FIGS. 1A-1B, and that has at least some of the channel regions 103 extending from a corresponding first diffusion region to a corresponding second diffusion region, in accordance with an embodiment of the present disclosure. Thus, for example, additional diffusion regions 105e, 105f, 105g, and 105h are present in the structure 100c of FIG. 1C. For example, the nanoribbons 103a of FIG. 1C extend from the diffusion region 105e to the diffusion region 105a, the nanoribbons 103e of FIG. 1C extend from the diffusion region 105f to the diffusion region 105b, the nanoribbons 103d of FIG. 1C extend from the diffusion region 105c to the diffusion region 105g, and the nanoribbons 103h of FIG. 1C extend from the diffusion region 105d to the diffusion region 105h. In contrast, each of the nanoribbons 103b, 103f, 103c, and 103g extends from a corresponding diffusion region 105 to a structure comprising dielectric material 165.

FIG. 2 illustrates a cross-sectional view of an integrated circuit structure 200 that is at least in part similar to the integrated circuit structure 100 of FIGS. 1A-1B, and that has a first backside contact 257a at least in part extending within the first portion 140 of the sub-fin 139, and a second backside contact 257b at least in part extending within the second portion 142 of the sub-fin 139, in accordance with an embodiment of the present disclosure. Thus, while the backside contacts 157a, 157b of FIG. 1A were in contact with (and not extending within) the backside of the sub-fin 139, the backside contacts 257a, 257b of FIG. 2 extend at least in part within the sub-fin 139. For example, the contact 257a extends within the first portion 140 of the sub-fin 139 and is coupled to the diffusion region 105b, and the contact 257b extends within the second portion 142 of the sub-fin 139 and is coupled to the diffusion region 105d. The contacts 257a, 257b comprise conductive material, such as one or more metals and/or alloys thereof. Various components of the structure 200 of FIG. 2 will be apparent, based on the above discussion with respect to FIGS. 1A-1C. For example, a diode (e.g., similar to the diode 151 discussed above) may be formed, based on the PN junction 141 within the structure 200.

FIG. 3A illustrates a cross-sectional view of an integrated circuit structure 300 comprising (i) a sub-fin 139 having a first portion 140 doped with a first type of dopant and a second portion 142 doped with a second type of dopant, and (ii) one or more laterally adjacent devices 102b, 102d above the sub-fin 139, wherein a first backside contact 157a is in contact with the first portion 140 of the sub-fin 139, and a second backside contact 157b is in contact with the second portion 142 of the sub-fin 139, in accordance with an embodiment of the present disclosure. Thus, the structure 300 is at least in part similar to the structure 100 discussed above. However, unlike the structure 100 that had stacked upper and lower devices 102a, . . . , 102d, the structure 300 comprises laterally adjacent devices 102b and 102d, as illustrated in FIG. 3A. The structure 300 will be apparent, based on the discussion with respect to the structure 100 of FIGS. 1A-1C.

Note that as discussed above, in the structure 100 of FIGS. 1A-1C, the upper diffusion regions 105a and 105c are doped with a first type of dopant, and the lower diffusion regions 105b and 105d are doped with a second type of dopant, where the first type of dopant is one of a p-type or an n-type dopant, and where the second type of dopant is the other of the p-type or the n-type dopant. For example, the upper diffusion regions 105a and 105c of FIGS. 1A-1C may be doped with n-type dopant, and the lower diffusion regions 105a and 105c of FIGS. 1A-1C may be doped with p-type dopant. Thus, in FIGS. 1A-1C, the upper devices 102a, 102c may be NMOS devices, whereas the lower devices 102b, 102d may be PMOS devices.

In contrast, in the structure 300 of FIG. 3A comprising laterally adjacent devices, one of the diffusion regions 105b, 105d is doped with a p-type dopant, and the other of the diffusion regions 105b, 105d is doped with an n-type dopant. For example, the portion 140 and the diffusion region 105b are doped with a same type of dopant (such as a p-type dopant, for example), and the portion 142 and the diffusion region 105d are doped with a same type of dopant (such as an n-type dopant, for example).

FIG. 3B illustrates a cross-sectional view of an integrated circuit structure 300b that is at least in part similar to the integrated circuit structure 300 of FIG. 3A, and that has a first backside contact 357a at least in part extending within the first portion 140 of the sub-fin 139, and a second backside contact 357b at least in part extending within the second portion 142 of the sub-fin 139, in accordance with an embodiment of the present disclosure. Thus, while the backside contacts 157a, 157b of FIG. 3A were in contact with (and not extending within) the backside of the sub-fin 139, the backside contacts 357a, 357b of FIG. 3B extend at least in part within the sub-fin 139. For example, the contact 357a extends within the first portion 140 of the sub-fin 139 and is coupled to the diffusion region 105b, and the contact 357b extends within the second portion 142 of the sub-fin 139 and is coupled to the diffusion region 105d. The contacts 357a, 357b comprise conductive material, such as one or more metals and/or alloys thereof. Various components of the structure 300b of FIG. 3B will be apparent, based on the above discussion with respect to FIGS. 1A-3A.

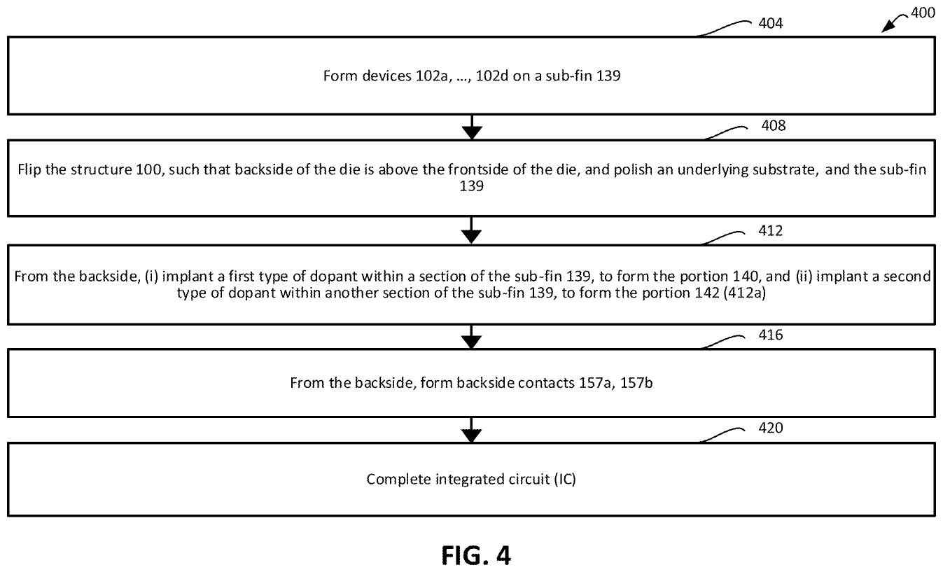

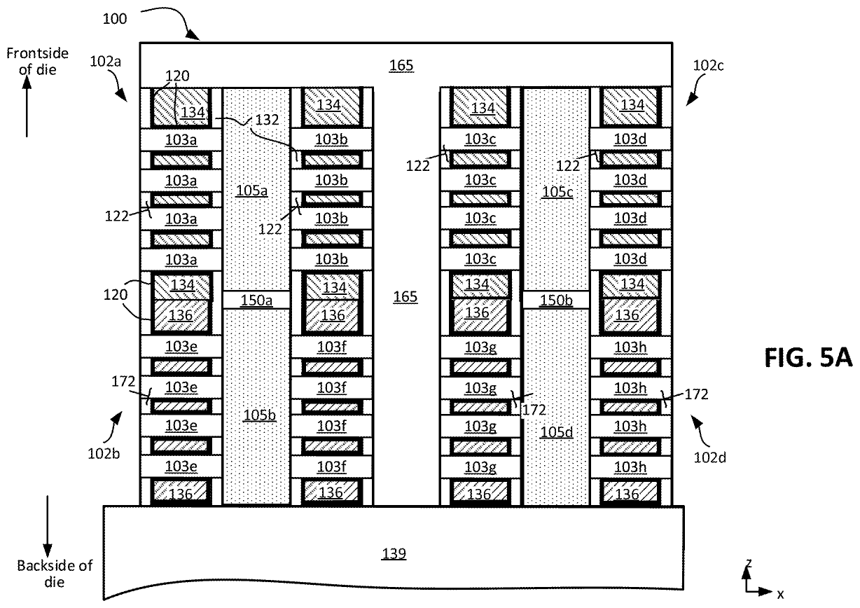

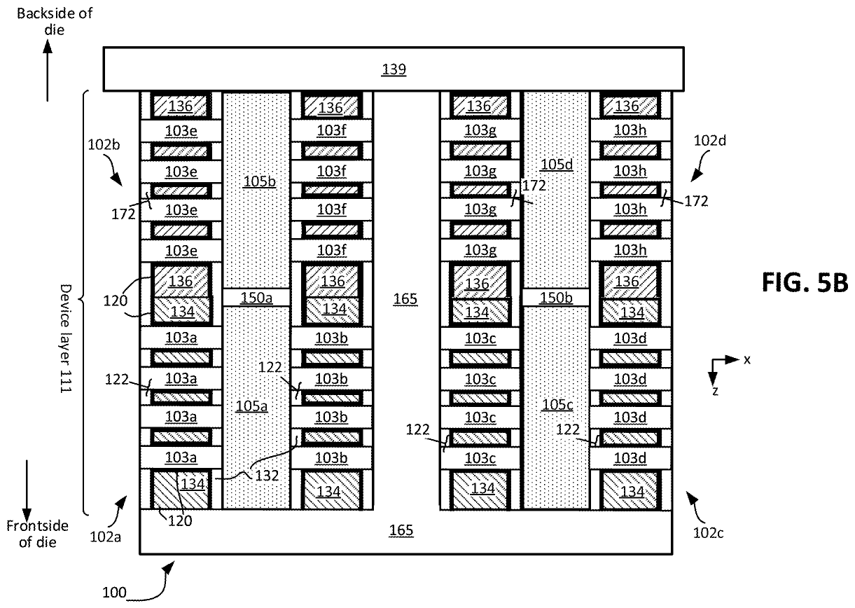

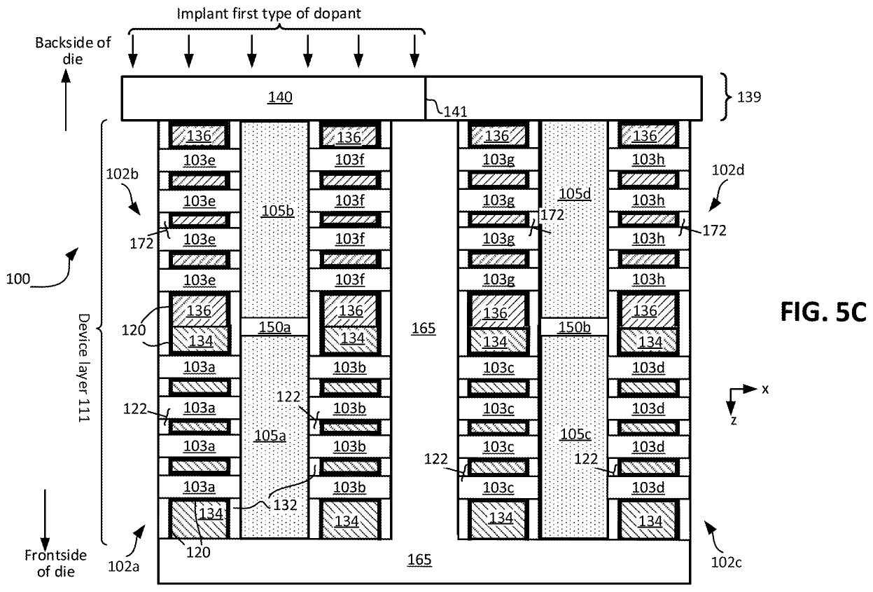

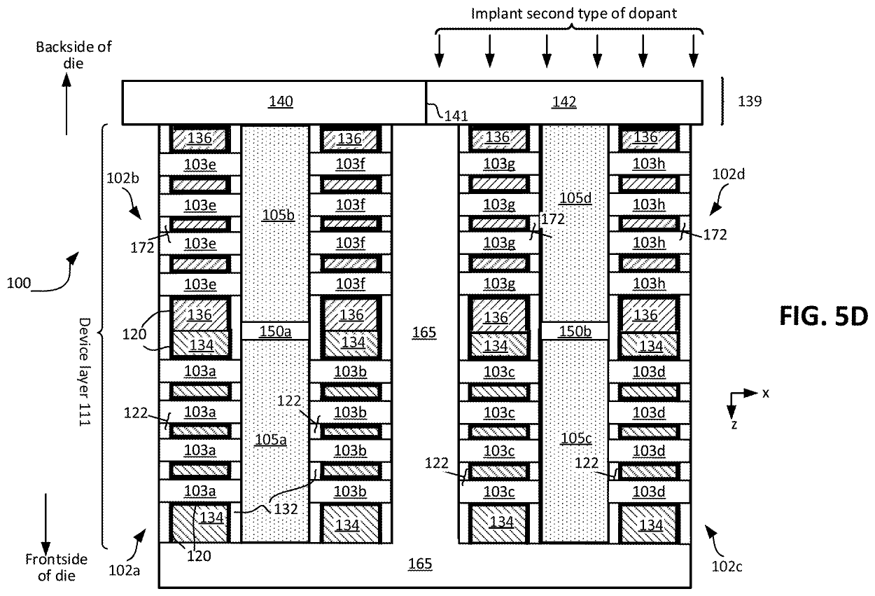

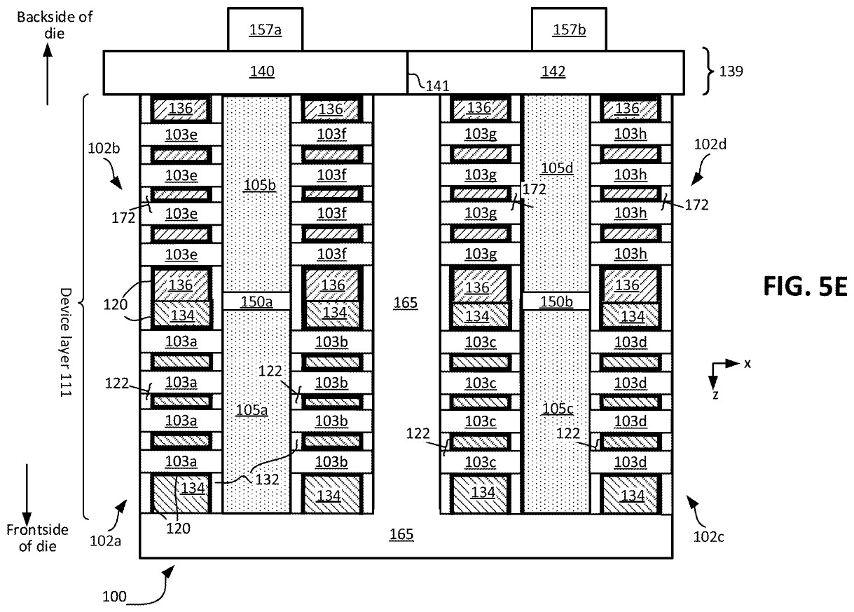

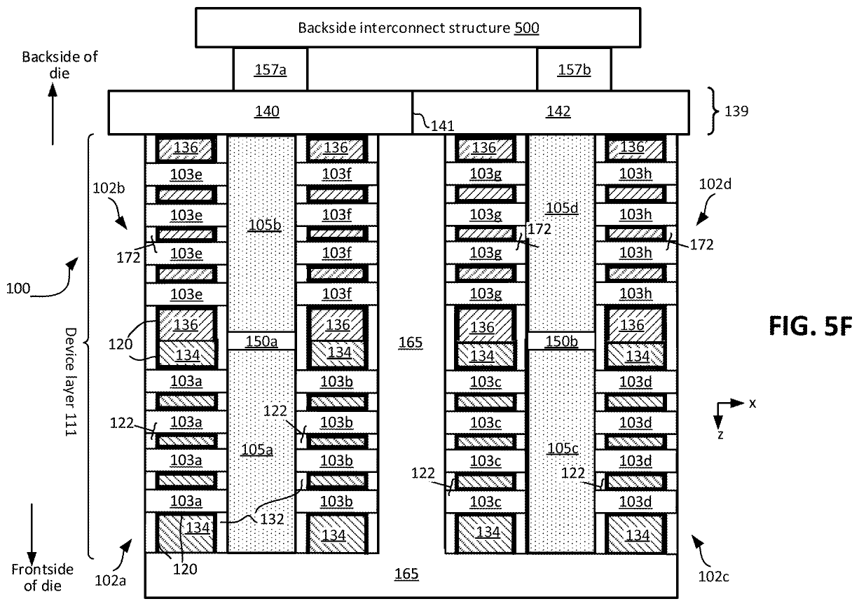

FIG. 4 illustrate a flowchart depicting a method 400 of forming the integrated circuit structure 100 of FIGS. 1A-1C, in accordance with an embodiment of the present disclosure. FIGS. 5A, 5B, 5C, 5D, 5E, and 5F collectively illustrate cross-sectional views of an example semiconductor structure (e.g., the semiconductor structure 100) in various stages of processing in accordance with the methodology 400 of FIG. 4, in accordance with an embodiment of the present disclosure. FIGS. 4 and 5A-5F will be discussed in unison.

Referring to FIG. 4, the method 400 includes, at 404, forming devices 102a, . . . , 102d on a sub-fin 139, e.g., as illustrated in FIG. 5A. The devices 102a, . . . , 102d may be formed using techniques to form vertically stacked GAA devices.

Referring again to FIG. 4, the method 400 proceeds from 404 to 408, where the structure 100 is flipped, such that backside of the die is now above the frontside of the die. Furthermore, also at 408, from the backside of the die (which is now above the frontside, and the processing is from the top of the die), an underlying substrate and a section of the sub-fin 139 is polished and at least in part etched, e.g., using a chemical and mechanical polishing (CMP), as illustrated in FIG. 5B.

Referring again to FIG. 4, the method 400 proceeds from 408 to 412, where from the backside, a first type of dopant (e.g., one of a p-type dopant or an n-type dopant) is implanted within a section of the sub-fin 139, to form the portion 140, as illustrated in FIG. 5C. Also, a second type of dopant (e.g., the other of the p-type dopant or the n-type dopant) is implanted within another section of the sub-fin 139, to form the portion 142, as illustrated in FIG. 5D.

In an example, when the first type of dopant is being implanted within the portion 140, the portion 142 may be masked off to prevent implantation of the first type of dopant within the portion 142. Similarly, when the second type of dopant is being implanted within the portion 142, the portion 140 may be masked off to prevent implantation of the first type of dopant within the portion 140.

Note that although portion 140 is doped prior to the portion 142 in the example of FIGS. 4, 5C, and 5D, in another example, the portion 142 may be doped prior to the portion 140. In an example, subsequent to the implantation, the structure 100 may be annealed, to activate the dopants. In an example, an appropriate low temperature anneal process may be used to activate the dopants.

However, in another example and contrary to the method 400 of FIG. 4, instead of at process 412, the implantation process may be performed from the frontside, e.g., prior to flipping the structure 100 at process 404. For example, the sub-fin 139 may be implanted (e.g., from the frontside) with appropriate type of dopants, to form portions 140 and 142, and subsequently, the devices 102a, . . . , 102d may be formed on the sub-fin 139 comprising the portions 140 and 142. In an example, the implantation from the frontside may be performed at any stage of frontside processing of the structure, e.g., prior to flipping the structure 100 at process 404. Thus, if the sub-fin 139 is implanted from the frontside, the process 412 is skipped, in an example.

Referring again to FIG. 4, the method 400 proceeds from 412 to 416, where from the backside, the backside contacts 157a, 157b are formed, as illustrated in FIG. 5E. The backside contacts 157a, 157b are formed using appropriate techniques for forming backside contacts.

The method 400 then proceeds from 416 to 420, where a general integrated circuit (IC) is completed, as desired, in accordance with some embodiments. Such additional processing to complete an IC may include forming a backside interconnect structure 500 (illustrated in FIG. 5F, and not in FIG. 1A), back-end or back-end-of-line (BEOL) processing to form one or more metallization layers and/or to interconnect the transistor devices formed, for example. Any other suitable processing may be performed, as will be apparent in light of this disclosure. In an example, the backside interconnect structure 500 comprises one or more interconnect layers, where each interconnect layer comprises corresponding dielectric material, and a plurality of interconnect features (such as vias and conductive lines) within the dielectric material. In an example, the backside interconnect structure 500 couples the contact 157a to one of a power rail (or an input/output terminal) or a ground terminal, and couples the contact 157b to the other of the power rail (or the input/output terminal) or the ground terminal, e.g., depending on an application of the diode 151 (see FIG. 1B for the diode 151).

Note that the processes in method 400 are shown in a particular order for ease of description. However, one or more of the processes may be performed in a different order or may not be performed at all (and thus be optional), in accordance with some embodiments. Numerous variations on method 400 and the techniques described herein will be apparent in light of this disclosure.

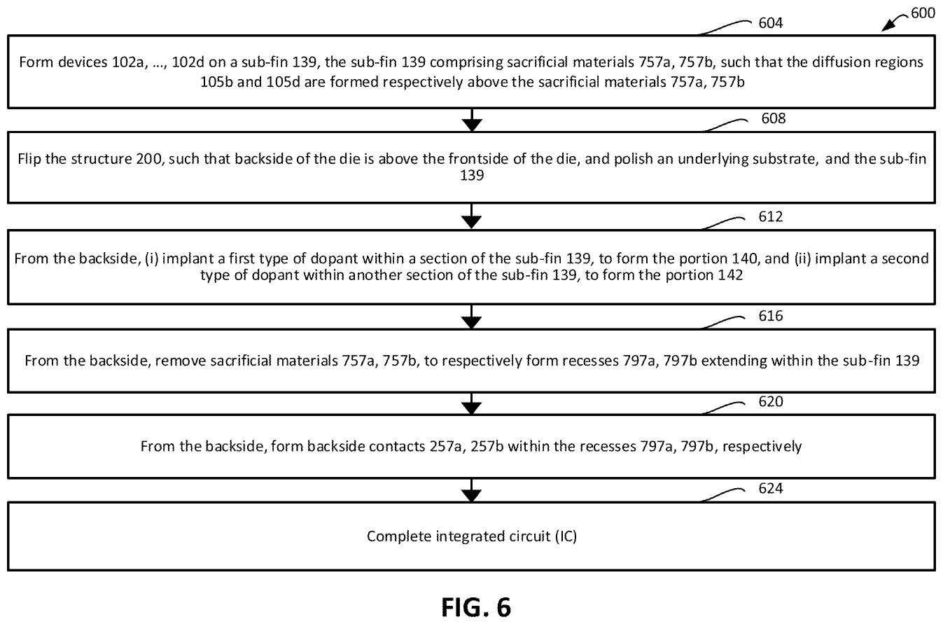

FIG. 6 illustrate a flowchart depicting a method 600 of forming the integrated circuit structure 200 of FIG. 2, in accordance with an embodiment of the present disclosure. FIGS. 7A, 7B, 7C, 7D, 7E, 7F, and 7G collectively illustrate cross-sectional views of an example semiconductor structure (e.g., the semiconductor structure 200) in various stages of processing in accordance with the methodology 600 of FIG. 6, in accordance with an embodiment of the present disclosure. FIGS. 6 and 7A-7G will be discussed in unison.

Referring to FIG. 6, the method 600 includes, at 604, forming devices 102a, . . . , 102d on a sub-fin 139, where the sub-fin 139 comprises sacrificial materials 757a, 757b, such that the diffusion regions 105b and 105d are formed respectively above the sacrificial materials 757a, 757b, as illustrated in FIG. 7A. The devices 102a, . . . , 102d may be formed using appropriate techniques to form vertically stacked GAA devices. In an example, during formation of the devices 102a, . . . , 102d, from the frontside of the die, sections of the sub-fin 139 may be etched and filed with the sacrificial materials 757a, 757b. The diffusion regions may then be formed above respective sacrificial materials 757a, 757b.

Referring again to FIG. 6, the method 600 proceeds from 604 to 608, where the structure 200 is flipped, such that backside of the die is now above the frontside of the die. Furthermore, also at 608, from the backside of the die (which is now above the frontside), an underlying substrate and a section of the sub-fin 139 is polished and at least in part etched, e.g., using a chemical and mechanical polishing (CMP), as illustrated in FIG. 7B.

Referring again to FIG. 6, the method 600 proceeds from 608 to 612, where from the backside, a first type of dopant (e.g., one of a p-type dopant or an n-type dopant) is implanted within a section of the sub-fin 139, to form the portion 140, as illustrated in FIG. 7C. Also, a second type of dopant (e.g., the other of the p-type dopant or the n-type dopant) is implanted within another section of the sub-fin 139, to form the portion 142, as illustrated in FIG. 7D.

In an example, when dopants are being implanted within the portion 140, the portion 142 may be masked off to prevent implantation of the first type of dopant within the portion 142. Similarly, when dopants are being implanted within the portion 142, the portion 140 may be masked off to prevent implantation of the first type of dopant within the portion 140.

Note that although portion 140 is formed prior to the portion 142 in the example of FIGS. 6, 7C, and 7D, in another example, the portion 142 may be formed prior to the portion 140. In an example, subsequent to the implantation, the structure 200 may be annealed, to activate the dopants. In an example, an appropriate low temperature anneal process may be used to activate the dopants.

However, in another example, instead of at process 612, the implantation process may be performed from the frontside, e.g., prior to flipping the structure 200 at process 604. For example, the sub-fin 139 may be implanted with appropriate type of dopants (e.g., from the frontside), to form portions 140 and 142, and the devices 102a, . . . , 102d may be formed within the sub-fin 139 comprising the portions 140 and 142.

Referring again to FIG. 6, the method 600 proceeds from 612 to 616, where from the backside, the sacrificial materials 757a, 757b are removed (e.g., using an appropriate selective etch process), to respectively form recesses 797a, 797b extending within the sub-fin 139, as illustrated in FIG. 7E. The etch process is selective, such that the sacrificial materials 757a, 757b are removed, without substantially removing the sub-fin 139 or other components of the structure 200.

Referring again to FIG. 6, the method 600 proceeds from 616 to 620, where from the backside, the backside contacts 257a, 257b are formed within the recesses 797a, 797b, respectively, as illustrated in FIG. 7F. The backside contacts 257a, 257b are formed using appropriate techniques for forming backside contacts. The structure of FIG. 7F is a flipped (e.g., upside-down) version of the structure 200 of FIG. 2.

The method 600 then proceeds from 620 to 624, where a general integrated circuit (IC) is completed, as desired, in accordance with some embodiments. Such additional processing to complete an IC may include forming conductive interconnect features 777a, 777b (such as conductive vias or conductive lines, such as metal lines) connected to the backside of the contacts 257a, 257b, and forming a backside interconnect structure 700 (illustrated in FIG. 7G, and not in FIG. 2), back-end or back-end-of-line (BEOL) processing to form one or more metallization layers and/or to interconnect the transistor devices formed, for example. Any other suitable processing may be performed, as will be apparent in light of this disclosure. In an example, the backside interconnect structure 700 comprises one or more interconnect layers, where each interconnect layer comprises corresponding dielectric material, and a plurality of interconnect features (such as vias and conductive lines) within the dielectric material. In an example, the backside interconnect structure 700 couples the contact 257a to one of a power rail (or an input/output terminal) or a ground terminal, and couples the contact 257b to the other of the power rail (or the input/output terminal) or the ground terminal, e.g., depending on an application of the diode 151 (see FIG. 1B for the diode 151).

Note that the processes in method 600 are shown in a particular order for ease of description. However, one or more of the processes may be performed in a different order or may not be performed at all (and thus be optional), in accordance with some embodiments. Numerous variations on method 600 and the techniques described herein will be apparent in light of this disclosure.

### Example System

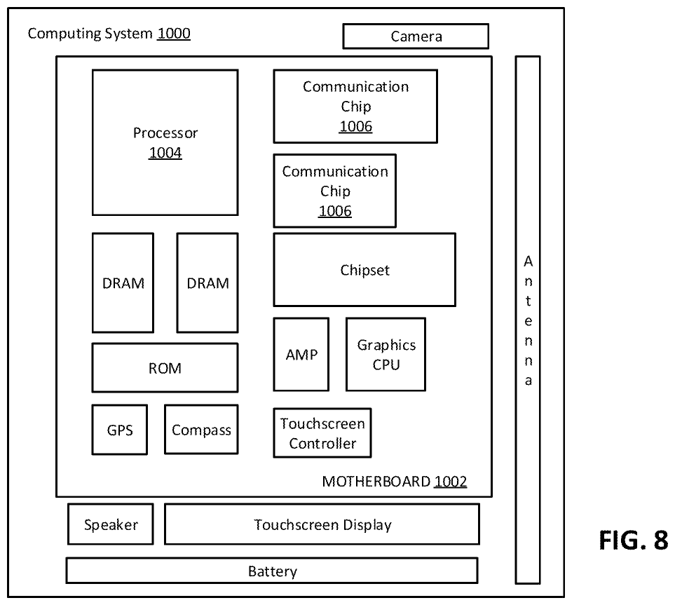

FIG. 8 illustrates a computing system 1000 implemented with integrated circuit structures formed using the techniques disclosed herein, in accordance with some embodiments of the present disclosure. As can be seen, the computing system 1000 houses a motherboard 1002. The motherboard 1002 may include a number of components, including, but not limited to, a processor 1004 and at least one communication chip 1006, each of which can be physically and electrically coupled to the motherboard 1002, or otherwise integrated therein. As will be appreciated, the motherboard 1002 may be, for example, any printed circuit board, whether a main board, a daughterboard mounted on a main board, or the only board of system 1000, etc.

Depending on its applications, computing system 1000 may include one or more other components that may or may not be physically and electrically coupled to the motherboard 1002. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 1000 may include one or more integrated circuit structures or devices formed using the disclosed techniques in accordance with an example embodiment. In some embodiments, multiple functions can be integrated into one or more chips (e.g., for instance, note that the communication chip 1006 can be part of or otherwise integrated into the processor 1004).

The communication chip 1006 enables wireless communications for the transfer of data to and from the computing system 1000. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1006 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 1000 may include a plurality of communication chips 1006. For instance, a first communication chip 1006 may be dedicated to shorter range wireless communications such as Wi-Fi and Bluetooth and a second communication chip 1006 may be dedicated to longer range wireless communications such as GPS, EDGE, GPRS, CDMA, WiMAX, LTE, Ev-DO, and others.

The processor 1004 of the computing system 1000 includes an integrated circuit die packaged within the processor 1004. In some embodiments, the integrated circuit die of the processor includes onboard circuitry that is implemented with one or more integrated circuit structures or devices formed using the disclosed techniques, as variously described herein. The term “processor” may refer to any device or portion of a device that processes, for instance, electronic data from registers and/or memory to transform that electronic data into other electronic data that may be stored in registers and/or memory.

The communication chip 1006 also may include an integrated circuit die packaged within the communication chip 1006. In accordance with some such example embodiments, the integrated circuit die of the communication chip includes one or more integrated circuit structures or devices formed using the disclosed techniques as variously described herein. As will be appreciated in light of this disclosure, note that multi-standard wireless capability may be integrated directly into the processor 1004 (e.g., where functionality of any chips 1006 is integrated into processor 1004, rather than having separate communication chips). Further note that processor 1004 may be a chip set having such wireless capability. In short, any number of processor 1004 and/or communication chips 1006 can be used. Likewise, any one chip or chip set can have multiple functions integrated therein.

In various implementations, the computing system 1000 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device or system that processes data or employs one or more integrated circuit structures or devices formed using the disclosed techniques, as variously described herein. Note that reference to a computing system is intended to include computing devices, apparatuses, and other structures configured for computing or processing information.

### Further Example Embodiments

The following examples pertain to further embodiments, from which numerous permutations and configurations will be apparent.

Example 1. An integrated circuit structure comprising: a sub-fin having at least (i) a first portion that is doped with a first type of dopant, and (ii) a second portion that is doped with a second type of dopant, with a PN junction between the first and second portions of the sub-fin, wherein the first type of dopant is one of a p-type or an n-type dopant, and wherein the second type of dopant is the other of the p-type or the n-type dopant; and a first contact and a second contact comprising conductive material, the first contact and the second contact respectively in contact with the first portion and the second portion of the sub-fin.

Example 2. The integrated circuit structure of example 1, further comprising: one or more devices above the sub-fin, wherein at least one device of the one or more devices comprises a diffusion region, and a body of semiconductor material extending laterally from the diffusion region, the body of semiconductor material above the sub-fin.

Example 3. The integrated circuit structure of example 2, wherein the at least one device of the one or more devices comprises a gate structure at least in part wrapping around the body, the gate structure comprising a gate electrode, and a gate dielectric between the gate electrode and the body.

Example 4. The integrated circuit structure of any one of examples 2-3, wherein: the at least one device is a first device of the one or more devices, the diffusion region is a first diffusion region, the body is a first body; and the one or more devices comprises a second device stacked above the first device, the second device comprising a second diffusion region, and a second body of semiconductor material extending from the second diffusion region, the second body of semiconductor material above the sub-fin.

Example 5. The integrated circuit structure of any one of examples 2-4, further comprising: an isolation structure comprising dielectric material between the first diffusion region and the second diffusion region.

Example 6. The integrated circuit structure of any one of examples 2-4, further comprising: a conductive via structure between the first diffusion region and the second diffusion region.

Example 7. The integrated circuit structure of any one of examples 2-6, wherein the first contact extends within the first portion of the sub-fin and is in contact with the first diffusion region, and wherein the second contact extends within the second portion of the sub-fin and is in contact with a second diffusion region of a second device that is laterally adjacent to the first device.

Example 8. The integrated circuit structure of any one of examples 2-7, further comprising: a structure comprising dielectric material above, and in contact with the PN junction of the sub-fin, wherein the body of semiconductor material extends laterally from the diffusion region to the structure comprising dielectric material.

Example 9. The integrated circuit structure of any one of examples 2-8, wherein the body comprises one of a nanoribbon, a nanosheet, a nanowire, or a fin.

Example 9a. The integrated circuit structure of any one of examples 2-8, wherein the body is a first body, the integrated circuit structure comprising a second body of semiconductor material extending laterally from another diffusion region, and wherein the first body and the second body are arranged in a forksheet device configuration such that a dielectric material structure is laterally between the first and second bodies.

Example 10. The integrated circuit structure of any one of examples 2-9a, wherein: the at least one device is a first device of the one or more devices, the diffusion region is a first diffusion region, the body is a first body; and the one or more devices comprises a second device laterally adjacent to the first device, the second device comprising a second diffusion region, and a second body of semiconductor material extending from the second diffusion region, the second body of semiconductor material above the sub-fin.

Example 11. The integrated circuit structure of example 10, wherein the first diffusion region and the first body are above the first portion of the sub-fin, and the second diffusion region and the second body are above the second portion of the sub-fin.

Example 12. The integrated circuit structure of any one of examples 1-11, further comprising: a structure comprising dielectric material above, and in contact with the PN junction of the sub-fin.

Example 13. The integrated circuit structure of any one of examples 1-12, wherein the first contact extends at least in part within the first portion of the sub-fin, and the second contact extends at least in part within the second portion of the sub-fin.

Example 14. The integrated circuit structure of any one of examples 1-13, wherein the first contact contacts the first portion of the sub-fin from a backside of the sub-fin, and the second contact contacts the second portion of the sub-fin from the backside of the sub-fin, and wherein one or more devices are on a frontside of the sub-fin.

Example 15. The integrated circuit structure of any one of examples 1-14, further comprising: a backside interconnect structure below the sub-fin, the backside interconnect structure comprising one or more interconnect layers, each interconnect layer comprising dielectric material and one or more interconnect features within the dielectric material, wherein the backside interconnect structure is to transmit signal and/or power to and/or from the first contact and/or the second contact.

Example 16. The integrated circuit structure of any one of examples 1-15, wherein the sub-fin and the first and second contacts are a part of a diode structure, and wherein the integrated circuit structure further comprises: a logic transistor laterally adjacent to the diode structure and above a dielectric material, such that an imaginary horizontal line passes through the first and second portions of the sub-fin, the PN junction, and the dielectric material below the logic transistor.

Example 17. A diode structure comprising: a sub-fin having (i) a first portion that is an anode region, and (ii) a second portion that is a cathode region, with a PN junction between the first and second portions; and a first backside contact that is in contact with the first portion of the sub-fin, and a second backside contact that is in contact with the second portion of the sub-fin.

Example 18. The diode structure of example 17, wherein: a first diffusion region above the first portion of the sub-fin; a second diffusion region above the second portion of the sub-fin; and a structure comprising dielectric material above and in contact with the PN junction.

Example 19. The diode structure of example 18, wherein: a first body of semiconductor material extending laterally from the first diffusion region to the structure comprising dielectric material; and a second body of semiconductor material extending laterally from the second diffusion region to the structure comprising dielectric material.

Example 20. The integrated circuit structure of example 19, wherein each of the first and second bodies comprises one of a nanoribbon, a nanosheet, a nanowire, or a fin.

Example 21. The integrated circuit structure of example 19, wherein one or both the first body and the second body are arranged in a forksheet device configuration.

Example 22. An integrated circuit structure comprising: a sub-fin having a first portion and a second portion, with a PN junction at an interface between the first and second portions; a first diffusion region extending upward from the first portion of the sub-fin, and a second diffusion region extending upward from the second portion of the sub-fin; a first body of semiconductor material extending laterally from the first diffusion region, and a second body of semiconductor material extending laterally from the second diffusion region; and a first conductive contact in contact with the first portion of the sub-fin, and a second conductive contact in contact with the second portion of the sub-fin.

Example 23. The integrated circuit structure of example 22, wherein the first conductive contact extends at least in part within the first portion of the sub-fin, and the second conductive contact extends at least in part within the second portion of the sub-fin.

Example 24. The integrated circuit structure of any one of examples 22-23, wherein the first conductive contact and the second contact are at least in part below the sub-fin.

The foregoing description of example embodiments of the present disclosure has been presented for the purposes of illustration and description. It is not intended to be exhaustive or to limit the present disclosure to the precise forms disclosed. Many modifications and variations are possible in light of this disclosure. It is intended that the scope of the present disclosure be limited not by this detailed description, but rather by the claims appended hereto.

What is claimed is:

1. An integrated circuit structure comprising:
a sub-fin having at least (i) a first portion that is doped with a first type of dopant, and (ii) a second portion that is doped with a second type of dopant, with a PN junction between the first and second portions of the sub-fin, wherein the first type of dopant is one of a p-type or an n-type dopant, and wherein the second type of dopant is the other of the p-type or the n-type dopant; and
a first contact and a second contact comprising conductive material, the first contact and the second contact respectively in contact with the first portion and the second portion of the sub-fin.

2. The integrated circuit structure of claim 1, further comprising:
one or more devices above the sub-fin, wherein at least one device of the one or more devices comprises a diffusion region, and a body of semiconductor material extending laterally from the diffusion region, the body of semiconductor material above the sub-fin.

3. The integrated circuit structure of claim 2, wherein the at least one device of the one or more devices comprises a gate structure at least in part wrapping around the body, the gate structure comprising a gate electrode, and a gate dielectric between the gate electrode and the body.

4. The integrated circuit structure of claim 2, wherein:
the at least one device is a first device of the one or more devices, the diffusion region is a first diffusion region, the body is a first body; and
the one or more devices comprises a second device stacked above the first device, the second device comprising a second diffusion region, and a second body of semiconductor material extending from the second diffusion region, the second body of semiconductor material above the sub-fin.

5. The integrated circuit structure of claim 2, further comprising at least one of:
an isolation structure comprising dielectric material between the first diffusion region and the second diffusion region; or
a conductive via structure between the first diffusion region and the second diffusion region.

6. The integrated circuit structure of claim 2, wherein the first contact extends within the first portion of the sub-fin and is in contact with the first diffusion region, and wherein the second contact extends within the second portion of the sub-fin and is in contact with a second diffusion region of a second device that is laterally adjacent to the first device.

7. The integrated circuit structure of claim 2, further comprising:
a structure comprising dielectric material above, and in contact with the PN junction of the sub-fin, wherein the body of semiconductor material extends laterally from the diffusion region to the structure comprising dielectric material.

8. The integrated circuit structure of claim 2, wherein the body comprises one of a nanoribbon, a nanosheet, a nanowire, a fin, or is arranged in a forksheet device configuration.

9. The integrated circuit structure of claim 2, wherein:
the at least one device is a first device of the one or more devices, the diffusion region is a first diffusion region, the body is a first body; and
the one or more devices comprises a second device laterally adjacent to the first device, the second device comprising a second diffusion region, and a second body of semiconductor material extending from the second diffusion region, the second body of semiconductor material above the sub-fin.

10. The integrated circuit structure of claim 9, wherein the first diffusion region and the first body are above the first portion of the sub-fin, and the second diffusion region and the second body are above the second portion of the sub-fin.

11. The integrated circuit structure of claim 1, further comprising:
a structure comprising dielectric material above, and in contact with the PN junction of the sub-fin.

12. The integrated circuit structure of claim 1, wherein the first contact extends at least in part within the first portion of the sub-fin, and the second contact extends at least in part within the second portion of the sub-fin.

13. The integrated circuit structure of claim 1, wherein the first contact contacts the first portion of the sub-fin from a backside of the sub-fin, and the second contact contacts the second portion of the sub-fin from the backside of the sub-fin, and wherein one or more devices are on a frontside of the sub-fin.

14. The integrated circuit structure of claim 1, further comprising:
a backside interconnect structure below the sub-fin, the backside interconnect structure comprising one or more interconnect layers, each interconnect layer comprising dielectric material and one or more interconnect features within the dielectric material,
wherein the backside interconnect structure is to transmit signal and/or power to and/or from the first contact and/or the second contact.

15. The integrated circuit structure of claim 1, wherein the sub-fin and the first and second contacts are a part of a diode structure, and wherein the integrated circuit structure further comprises:
a logic transistor laterally adjacent to the diode structure and above a dielectric material, such that an imaginary horizontal line passes through the first and second portions of the sub-fin, the PN junction, and the dielectric material below the logic transistor.

16. A diode structure comprising:
a sub-fin having (i) a first portion that is an anode region, and (ii) a second portion that is a cathode region, with a PN junction between the first and second portions; and
a first backside contact that is in contact with the first portion of the sub-fin, and a second backside contact that is in contact with the second portion of the sub-fin.

17. The diode structure of claim 16, wherein:
a first diffusion region above the first portion of the sub-fin;
a second diffusion region above the second portion of the sub-fin; and
a structure comprising dielectric material above and in contact with the PN junction.

18. The diode structure of claim 17, wherein:
a first body of semiconductor material extending laterally from the first diffusion region to the structure comprising dielectric material; and
a second body of semiconductor material extending laterally from the second diffusion region to the structure comprising dielectric material.

19. An integrated circuit structure comprising:
a sub-fin having a first portion and a second portion, with a PN junction at an interface between the first and second portions;
a first diffusion region extending upward from the first portion of the sub-fin, and a second diffusion region extending upward from the second portion of the sub-fin;
a first body of semiconductor material extending laterally from the first diffusion region, and a second body of semiconductor material extending laterally from the second diffusion region; and
a first conductive contact in contact with the first portion of the sub-fin, and a second conductive contact in contact with the second portion of the sub-fin.

20. The integrated circuit structure of claim 19, wherein the first conductive contact extends at least in part within the first portion of the sub-fin, and the second conductive contact extends at least in part within the second portion of the sub-fin.
